(19) United States
(12) Patent Application Publication
(10) Pub. No.: US 2025/0338512 A1
(43) Pub. Date: Oct. 30, 2025

(54) SEMICONDUCTOR MEMORY DEVICE

(71) Applicant: Samsung Electronics Co., Ltd., Suwon-si (KR)

(72) Inventors: INHYUK BAE, Suwon-si (KR); SANG-HOON JUNG, Suwon-si (KR); YOUNG SEOK PARK, Suwon-si (KR); HYUN-CHUL YOON, Suwon-si (KR); YOUNGHUN SEO, Suwon-si (KR); CHANGSIK YOO, Suwon-si (KR)

(21) Appl. No.: 18/961,797

(22) Filed: Nov. 27, 2024

(30) Foreign Application Priority Data
Apr. 25, 2024 (KR) 10-2024-0055637

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2225/06541; H01L 2924/1431; H01L 2924/1436

(57) ABSTRACT

Provided is a semiconductor memory device. The semiconductor memory device includes a peripheral structure, a first upper cell structure on the peripheral structure, and a first lower cell structure on an opposite side of the peripheral structure from the first upper cell structure, wherein each of the first upper cell structure and the first lower cell structure includes a first active pattern perpendicular to an upper surface of the peripheral structure, a first word line adjacent to a side surface of the first active pattern and extending in a first direction parallel to the upper surface of the peripheral structure, and a first bit line electrically connected to a first end of the first active pattern and extending in a second direction intersecting the first direction.

### CROSS-REFERENCE TO RELATED APPLICATIONS

This U.S. non-provisional patent application claims priority under 35 U.S.C. § 119 to Korean Patent Application No. 10-2024-0055637, filed on Apr. 25, 2024, the entire contents of which are hereby incorporated by reference.

### BACKGROUND OF THE INVENTION

The present disclosure relates to a semiconductor memory device, and more particularly, to a semiconductor memory device including vertical channel transistors.

As a design rule for semiconductor elements decreases, a manufacturing technology is being developed to improve the integration, operational speed, and yield of semiconductor elements. Accordingly, transistors having vertical channels for increasing the integration, resistance, current driving ability, and the like of the transistors have been proposed.

### SUMMARY OF THE INVENTION

The present disclosure provides a semiconductor element with improved electrical characteristics and integration density.

The purposes of the present disclosure are not limited to the above-mentioned purposes, and other purposes not mentioned will be clearly understood by those skilled in the art from the disclosure below.

According to some aspects of the inventive concepts, a semiconductor memory device includes: a peripheral structure; a first upper cell structure on the peripheral structure; and a first lower cell structure on an opposite side of the peripheral structure from the first upper cell structure, wherein each of the first upper cell structure and the first lower cell structure includes: a first active pattern perpendicular to an upper surface of the peripheral structure, a first word line adjacent to a side surface of the first active pattern and extending in a first direction parallel to the upper surface of the peripheral structure, and a first bit line electrically connected to a first end of the first active pattern and extending in a second direction intersecting the first direction.

According to some aspects of the inventive concepts, a semiconductor memory device includes: a peripheral structure; at least one upper cell structure on the peripheral structure; and at least one lower cell structure on an opposite side of the peripheral structure from the upper cell structure, wherein each of the upper cell structure and the lower cell structure includes an array of memory cells, and wherein the peripheral structure includes: a peripheral substrate; peripheral transistors and peripheral lines on an upper surface of the peripheral substrate; a peripheral interlayer insulating layer on the peripheral transistors and the peripheral lines; a peripheral lower insulating layer on a lower surface of the peripheral substrate; a peripheral upper pad at an upper end of the peripheral interlayer insulating layer; and a through via extending into the peripheral substrate and electrically connected to at least one of the peripheral lines.

According to some aspects of the inventive concepts, a semiconductor memory device includes: a peripheral structure; a first upper cell structure on the peripheral structure; and a first lower cell structure on an opposite side of the peripheral structure from the first upper cell structure, wherein the peripheral structure includes: a peripheral substrate; peripheral transistors and peripheral lines on an upper surface of the peripheral substrate; a peripheral interlayer insulating layer on the peripheral transistors and the peripheral lines; a peripheral lower insulating layer on a lower surface of the peripheral substrate; a peripheral upper pad at an upper end of the peripheral interlayer insulating layer; and a through via extending into the peripheral substrate and electrically connected to at least one of the peripheral lines, wherein each of the first upper cell structure and the first lower cell structure includes: a first active pattern perpendicular to an upper surface of the peripheral structure; a first word line adjacent to a side surface of the first active pattern and extending in a first direction parallel to the upper surface of the peripheral structure; a first bit line electrically connected to a first end of the first active pattern and extending in a second direction intersecting the first direction; a first electrode electrically connected to a second end of the first active pattern; a dielectric layer on the first electrode; and a second electrode on the dielectric layer, wherein the second end is opposite to the first end of the first active pattern, and wherein the first bit line is closer to the peripheral structure than the first electrode in each of the first upper cell structure and the first lower cell structure.

### BRIEF DESCRIPTION OF THE FIGURES

The accompanying drawings are included to provide a further understanding of the inventive concepts, and are incorporated in and constitute a part of this specification. The drawings illustrate example embodiments of the inventive concepts and, together with the description, serve to explain principles of the inventive concepts. In the drawings:

FIG. 1A is a block diagram illustrating a semiconductor element including a semiconductor device according to embodiments of the inventive concepts;

FIG. 1B is a block diagram schematically illustrating a semiconductor memory device according to embodiments of the inventive concepts;

FIG. 2 is a perspective view of a semiconductor memory device according to embodiments of the inventive concepts;

FIG. 3 is a cross-sectional view taken along line A-A′ of FIG. 2 according to embodiments of the inventive concepts;

FIG. 4 is an enlarged view of the portion P1 of FIG. 3 according to embodiments of the inventive concepts;

FIGS. 5A and 5B are diagrams sequentially illustrating a process of manufacturing the semiconductor memory device of FIG. 2;

FIG. 6A is a cross-sectional view of the semiconductor memory device of FIG. 2 taken along line A-A′ according to embodiments of the inventive concepts;

FIG. 6B is a cross-sectional view of the semiconductor memory device of FIG. 2 taken along line A-A′ according to embodiments of the inventive concepts;

FIGS. 7A to 7D sequentially illustrate a process of manufacturing the semiconductor memory device of FIG. 6B according to embodiments of the inventive concepts;

FIG. 8A is a block diagram schematically illustrating a semiconductor memory device according to embodiments of the inventive concepts;

FIG. 8B is a block diagram schematically illustrating a semiconductor memory device according to embodiments of the inventive concepts;

FIG. 9 is a cross-sectional view of a semiconductor memory device according to embodiments of the inventive concepts;

FIG. 10 is a block diagram schematically illustrating a semiconductor memory device according to embodiments of the inventive concepts;

FIG. 11 is a block diagram schematically illustrating a semiconductor memory device according to embodiments of the inventive concepts; and

FIG. 12 is a block diagram schematically illustrating a semiconductor memory device according to embodiments of the inventive concepts.

### DETAILED DESCRIPTION

Hereinafter, example embodiments according to the inventive concepts will be described in detail with reference to the drawings in order to describe the inventive concepts in more detail. Herein, the terms indicating order, such as first, second, etc., are used to distinguish elements having the same/similar functions, and the ordinal numbers may be interchanged according to the order in which the terms are mentioned.

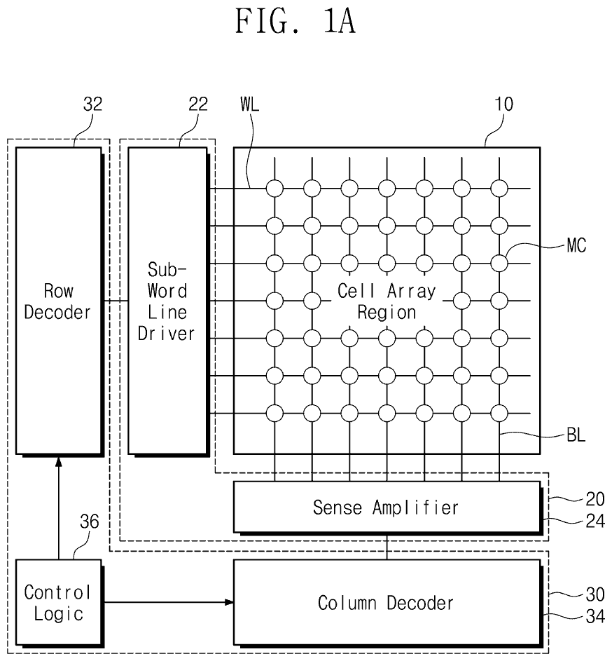

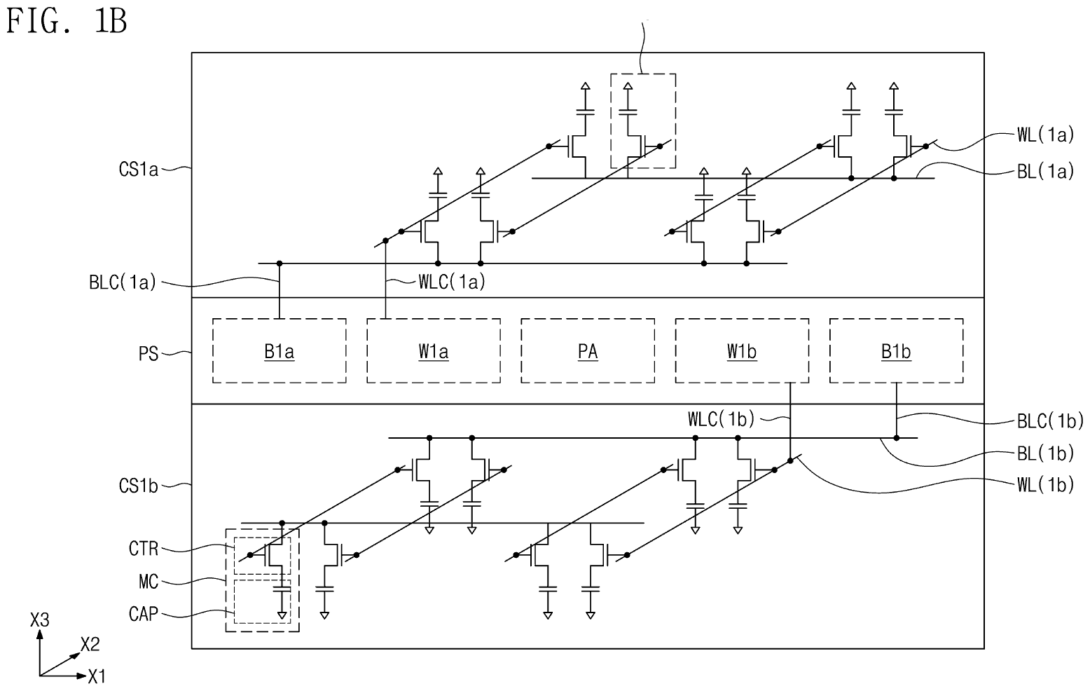

FIG. 1A is a block diagram illustrating a semiconductor element including a semiconductor device according to embodiments of the inventive concepts.

Referring to FIG. 1A, a semiconductor memory device according to the present example may include a cell array region 10. Word lines WL and bit lines BL intersecting each other may be arranged in the cell array region 10. A plurality of memory cells MC may be two-dimensionally or three-dimensionally arranged in the cell array region 10. Each of the memory cells MC may be connected between the word line WL and the bit line BL intersecting each other.

A core circuit unit 20 may be disposed at a periphery of the cell array region 10. A sub-word line driver 22 and a sense amplifier 24 may be arranged in the core circuit unit 20. A peripheral circuit unit 30 may be disposed at a periphery of the core circuit unit 20. A row decoder 32, a column decoder 34, and a control logic 36 may be arranged in the peripheral circuit unit 30.

The row decoder 32 may decode an externally input row address signal or refresh address signal. The sub-word line driver 22 may perform a function of selecting a particular word line WL in response to a row address signal or a refresh address signal.

The sense amplifier 24 may sense and amplify a voltage difference between a reference bit line and the bit line BL selected according to an address decoded by the column decoder 34 and output the amplified voltage difference.

The column decoder 34 may provide a data transmission path between the sense amplifier 24 and an external device (e.g., a memory controller). The column decoder 34 may decode an externally input column address signal and select any one of the bit lines BL.

The control logic 36 may generate control signals for controlling operations of writing or reading data to or from a memory cell array of the cell array region 10.

FIG. 1B is a block diagram schematically illustrating a semiconductor memory device according to embodiments of the inventive concepts.

Referring to FIG. 1B, a semiconductor memory device 1000 may include a first lower cell structure CS1b, a peripheral structure PS, and a first upper cell structure CS1a that are sequentially stacked. A core circuit unit and a peripheral circuit unit PA may be arranged in the peripheral structure PS. The core circuit unit may include a first upper sense amplifier B1a, a first lower sense amplifier B1b, a first upper word line driver W1a, and a first lower word line driver W1b. The first upper sense amplifier B1a and the first lower sense amplifier B1b may each correspond to the sense amplifier 24 of FIG. 1A. The first upper word line driver W1a and the first lower word line driver W1b may each correspond to the sub-word line driver 22 of FIG. 1A. The row decoder 32, the column decoder 34, and the control logic 36 may be arranged in the peripheral circuit unit PA.

The first lower cell structure CS1b and the first upper cell structure CS1a may each include memory cells MC that are two-dimensionally arranged on a plane extending in a first direction X1 and a second direction X2. The first and second directions X1 and X2 may be parallel to an upper surface of the peripheral structure PS and intersect each other. The memory cells MC may each include a cell transistor CTR and a capacitor CAP. As used herein, the capacitor CAP may also be referred to as a cell capacitor CAP.

The cell transistor CTR may be a field effect transistor (FET). A gate electrode of the cell transistor CTR may be connected to the word line WL, and drain/source terminals of the cell transistor CTR may be respectively connected to the bit line BL and the capacitor CAP. According to embodiments, the cell transistor CTR of each memory cell MC may be a vertical channel transistor (VCT). The vertical channel transistor may have a structure in which a channel extends in a direction (i.e., a third direction X3) perpendicular to the upper surface of the peripheral structure PS. In some embodiments, the capacitor CAP may be replaced with a magnetic tunnel junction pattern, a variable resistor, or the like. The memory cells MC may be located at intersections between the bit lines BL and the word lines WL. The word lines WL may correspond to gates of the cell transistors CTR.

The bit lines BL may include first upper bit lines BL(1a) belonging to the first upper cell structure CS1a and first lower bit lines BL(1b) belonging to the first lower cell structure CS1b. The word lines WL may include first upper word lines WL(1a) belonging to the first upper cell structure CS1a and first lower word lines WL(1b) belonging to the first lower cell structure CS1b.

The bit lines BL may be electrically connected by bit line contact plugs BLC to the peripheral structure PS. The bit line contact plugs BLC may include first upper bit line contact plugs BLC(1a) and first lower bit line contact plugs BLC(1b). The word lines WL may be electrically connected by word line contact plugs WLC to the peripheral structure PS. The word line contact plugs WLC may include first upper word line contact plugs WLC(1a) and first lower word line contact plugs WLC(1b).

One end of each of the first upper bit lines BL(1a) of the first upper cell structure CS1a may be connected to the first upper sense amplifier B1a of the peripheral structure PS through the first upper bit line contact plug BLC(1a). One end of each of the first lower bit lines BL(1b) of the first lower cell structure CS1b may be connected to the first lower sense amplifier B1b of the peripheral structure PS through the first lower bit line contact plug BLC(1b). The first upper bit line contact plug BLC(1a) may be disposed adjacent to a first sidewall of the peripheral structure PS. The first lower bit line contact plug BLC(1b) may be disposed adjacent to a second sidewall of the peripheral structure PS. The second sidewall may be opposite to the first sidewall. In other embodiments, in a plan view, the first upper bit line contact plugs BLC(1a) and the first lower bit line contact plugs BLC(1b) may be alternately arranged along the second direction X2.

One end of each of the first upper word lines WL(1a) of the first upper cell structure CS1a may be connected to the first upper word line driver W1a of the peripheral structure PS through the first upper word line contact plug WLC(1a). One end of each of the first lower word lines WL(1b) of the first lower cell structure CS1b may be connected to the first lower word line driver W1b of the peripheral structure PS through the first lower word line contact plug WLC(1b). The first upper word line contact plug WLC(1a) may be disposed adjacent to a third sidewall of the peripheral structure PS. The first lower word line contact plug WLC(1b) may be disposed adjacent to a fourth sidewall of the peripheral structure PS. The fourth sidewall may be opposite to the third sidewall. In other embodiments, in a plan view, the first upper word line contact plugs WLC(1a) and the first lower word line contact plugs WLC(1b) may be alternately arranged along the first direction X1.

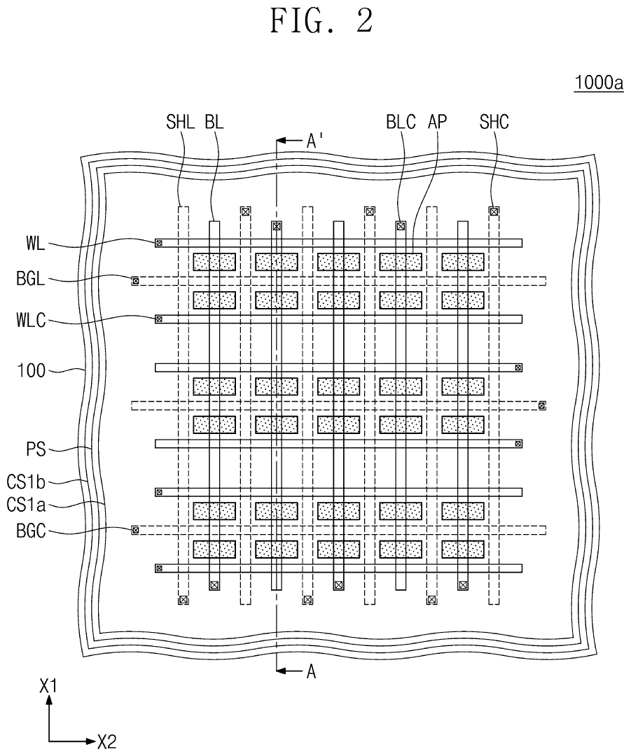

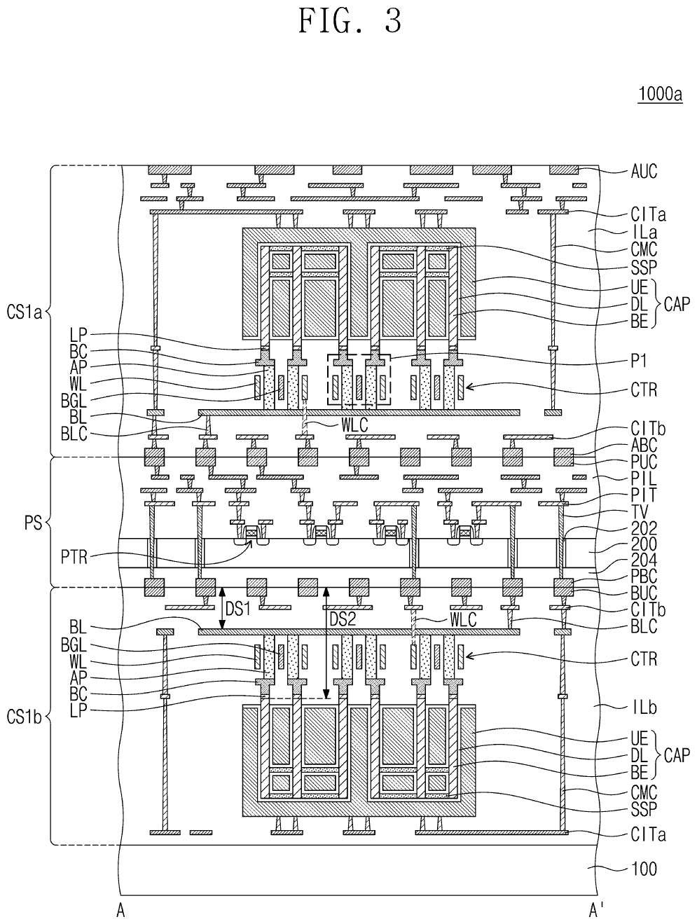

FIG. 2 is a perspective view of a semiconductor memory device according to embodiments of the inventive concepts. FIG. 3 is a cross-sectional view taken along line A-A′ of FIG. 2 according to embodiments of the inventive concepts.

Referring to FIGS. 2 and 3, in a semiconductor memory device 1000a according to the present example, the first lower cell structure CS1b, the peripheral structure PS, and the first upper cell structure CS1a may be sequentially stacked on a first support substrate 100. For example, the first upper cell structure CS1a may be on the peripheral structure PS, and the first lower cell structure CS1b may be on an opposite side of the peripheral structure PS from the first upper cell structure CS1a. The first support substrate 100 may be a semiconductor substrate, a silicon on insulator (SOI) substrate, or an insulating substrate.

The peripheral structure PS includes a peripheral substrate 200, peripheral transistors PTR and peripheral lines PIT arranged on an upper surface of the peripheral substrate 200, and a peripheral interlayer insulating layer PIL on (e.g., covering) the foregoing. The upper surface of the peripheral substrate 200 may be a front side of the peripheral substrate 200. The peripheral substrate 200 may be a semiconductor substrate, a silicon on insulator (SOI) substrate, or an insulating substrate.

The peripheral transistors PTR and the peripheral lines PIT may constitute the peripheral circuit unit PA, the first upper sense amplifier B1a, the first lower sense amplifier B1b, the first upper word line driver W1a, and the first lower word line driver W1b described with reference to FIG. 1B. The peripheral transistors PTR may each have a type of a planar transistor, a fin field-effect transistor (FinFET), a multi-bridge channel FET (MBCFET), a gate all around (GAA) transistor, or a buried channel array transistor (BCAT).

A lower surface of the peripheral substrate 200 is covered with a peripheral lower insulating layer 204. That is, the peripheral lower insulating layer 204 may be on the lower surface of the peripheral substrate 200. The lower surface of the peripheral substrate 200 may be a backside of the peripheral substrate 200. Peripheral upper pads PUC may be arranged at an upper end of the peripheral interlayer insulating layer PIL and connected to the peripheral lines PIT. Peripheral lower pads PBC may be arranged at a lower end of the peripheral lower insulating layer 204. The peripheral substrate 200 may be penetrated by through vias TV. That is, the through vias TV may extend into the peripheral substrate 200. The through vias TV may connect a portion of the peripheral lines PIT to the peripheral lower pads PBC. A peripheral substrate insulating pattern 202 may be interposed between the peripheral substrate 200 and the through vias TV. The peripheral substrate insulating pattern 202 may penetrate (i.e., extend into) the peripheral substrate 200.

The peripheral lines PIT, the through vias TV, the peripheral upper pads PUC, and the peripheral lower pads PBC may each include metal such as copper, aluminum, tungsten, titanium, or tantalum. The peripheral interlayer insulating layer PIL, the peripheral lower insulating layer 204, and the peripheral substrate insulating pattern 202 may each have a single-layer or multi-layer structure of at least one of silicon oxide, silicon nitride, silicon oxynitride, SiCN, SiOCH, or porous insulator.

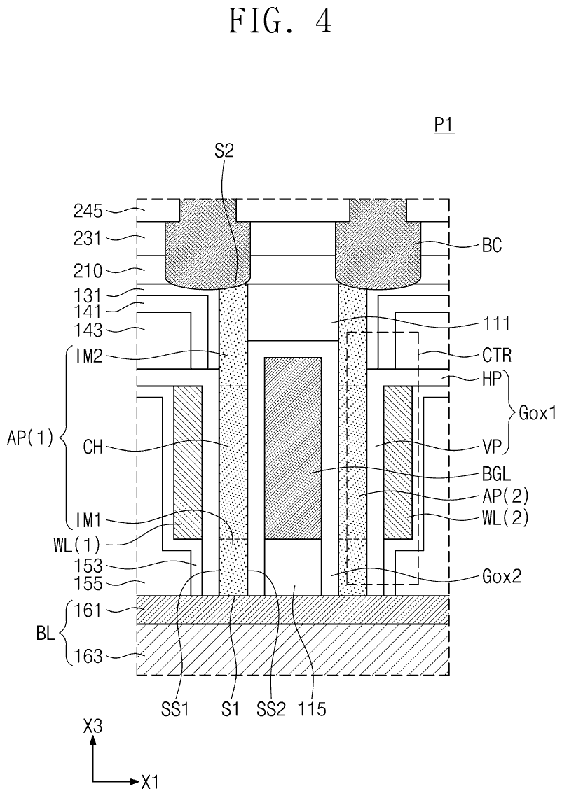

The first lower cell structure CS1b and the first upper cell structure CS1a each include active patterns AP perpendicular to the upper surface of the peripheral structure PS, word lines WL adjacent to one side surface of each of the active patterns AP and extending in the second direction X2 parallel to the upper surface of the peripheral structure PS, back gate lines BGL between adjacent active patterns AP, the bit lines BL connected to first ends S1 (see FIG. 4) of the active patterns AP and extending in the first direction X1, shield lines SHL between the bit lines BL, the word line contact plugs WLC, the bit line contact plugs BLC, back gate contact plugs BGC, shield line contact plugs SHC, etc. One of the active patterns AP and a portion of the word line WL adjacent thereto constitute the cell transistor CTR. For example, the cell transistors CTR may be closer to the peripheral structure PS than the capacitors CAP are in each of the first upper cell structure CS1a and the first lower cell structure CS1b.

The first lower cell structure CS1b further includes a first lower cell interlayer insulating layer ILb into which the active patterns AP, the word lines WL, and the bit lines BL are inserted. The first upper cell structure CS1a further includes a first upper cell interlayer insulating layer ILa into which the active patterns AP, the word lines WL, and the bit lines BL are inserted.

The first lower cell interlayer insulating layer ILb and the first upper cell interlayer insulating layer ILa may each have a single-layer or multi-layer structure of at least one of silicon oxide, silicon nitride, silicon oxynitride, SiCN, SiOCH, or porous insulator.

The first lower cell structure CS1b and the first upper cell structure CS1a may each further include a storage node contact BC, landing pads LP, and first electrodes BE connected to second ends S2 (see FIG. 4) of the active patterns AP. The first electrodes BE may be covered with a dielectric layer DL and a second electrode UE. That is, the dielectric layer DL and the second electrode UE may be on the first electrodes BE.

In each of the first lower cell structure CS1b and the first upper cell structure CS1a, the bit lines BL may be closer to the peripheral structure PS than the first electrodes BE. For example, in the first lower cell structure CS1b, a first distance DS1 between the bit line BL and the peripheral structure PS may be less than a second distance DS2 between the first electrode BE and the peripheral structure PS. The first lower cell structure CS1b may be similar to a structure that is mirror symmetrical to the first upper cell structure CS1a.

First lower cell pads BUC may be arranged at an upper end of the first lower cell structure CS1b and respectively in contact with the peripheral lower pads PBC. There may be no boundary surface between the first lower cell pads BUC and the peripheral lower pads PBC that are in contact with each other, and portions, which are in contact with each other, of those pads may be integrated.

The first lower cell structure CS1b may further include first cell lines CITa under the second electrode UE, second cell lines CITb between the first lower cell pads BUC and the bit lines BL, and cell contact plugs CMC connecting portions of the first and second cell lines CITa and CITb. For example, the first cell lines CITa and the second cell lines CITb may be in the first lower cell interlayer insulating layer ILb and may be electrically connected to the through vias TV.

First upper cell pads ABC may be arranged at a lower end of the first upper cell structure CS1a and respectively in contact with the peripheral upper pads PUC. Second upper cell pads AUC may be arranged at an upper end of the first upper cell structure CS1a. In the present example, the second upper cell pads AUC may be also referred to as “external connection pads”. A wire or solder ball may be bonded to the second upper cell pads AUC.

The first upper cell structure CS1a may further include first cell lines CITa between the second upper cell pads AUC and the second electrode UE, second cell lines CITb between the first upper cell pads ABC and the bit lines BL, and cell contact plugs CMC connecting portions of the first and second cell lines CITa and CITb.

The number of layers of the first cell lines CITa in the first upper cell structure CS1a may be greater than the number of layers of the first cell lines CITa in the first lower cell structure CS1b. A density of the first cell lines CITa in the first upper cell structure CS1a may be higher than a density of the first cell lines CITa in the first lower cell structure CS1b.

The first upper cell structure CS1a may be electrically connected to the peripheral structure PS through the first upper cell pads ABC and the peripheral upper pads PUC (e.g., in a copper-to-copper (Cu to Cu) manner). The first lower cell structure CS1b may be electrically connected to the peripheral structure PS through the first lower cell pads BUC, the peripheral lower pads PBC, and the through vias TV.

In detail, referring to FIGS. 2 to 4, the bit lines BL and the shield lines SHL may extend in the first direction X1 and may be spaced apart from each other in the second direction X2. The shield lines SHL may be respectively interposed between the bit lines BL. The bit lines BL and the shield lines SHL may be located at the same level.

The bit line contact plug BLC may be connected to the bit lines BL. The shield line contact plug SHC may be connected to the shield lines SHL. The word line contact plug WLC may be connected to the word line WL. The back gate contact plug BGC may be connected to the back gate line BGL.

FIG. 4 is an enlarged view of the portion P1 of FIG. 3 according to embodiments of the inventive concepts.

Referring to FIGS. 2 to 4, the cell transistors CTR respectively include the active patterns AP. The active patterns AP may include a pair of a first active pattern AP(1) and a second active pattern AP(2) adjacent to each other in the first direction X1. A channel region CH and first and second impurity regions IM1 and IM2 may be arranged in each of the active patterns AP. The first impurity regions IM1 of the active patterns AP may be in contact with the bit lines BL. The second impurity regions IM2 of the active patterns AP may be in contact with the storage node contact BC.

The word lines WL may include a pair of a first word line WL(1) and a second word line WL(2) adjacent to each other in the first direction X1. The first word line WL(1) may be adjacent to the channel region CH of the first active pattern AP(1). The second word line WL(2) may be adjacent to the channel region CH of the second active pattern AP(2).

First gate insulating layers Gox1 may be arranged between the first and second word lines WL(1) and WL(2) and the first and second active patterns AP(1) and AP(2). The first gate insulating layers Gox1 may extend in the second direction X2 in parallel with the first and second word lines WL(1) and WL(2).

The back gate line BGL is interposed between the pair of the first active pattern AP(1) and the second active pattern AP(2). The word lines WL and the back gate lines BGL may extend in the second direction X2 as illustrated in FIGS. 2 and 4. A second gate insulating layer Gox2 may be arranged between the back gate line BGL and the first and second active patterns AP(1) and AP(2). The first gate insulating layers Gox1 and the second gate insulating layer Gox2 may be formed of, for example, a silicon oxide layer, a silicon oxynitride layer, a high dielectric layer with a higher dielectric constant than a silicon oxide layer, or a combination thereof. The high dielectric layer may be formed of a metal oxide or metal oxynitride. For example, a high dielectric layer that may be used as the gate insulating layers Gox1 and Gox2 may be formed of HfO₂, HfSiO, HfSiON, HfTaO, HfTiO, HfZrO, ZrO₂, Al₂O₃, or a combination thereof, but is not limited thereto. A thickness of the first gate insulating layers Gox1 may be equal to or different from a thickness of the second gate insulating layer Gox2.

A portion of the first word line WL(1) and the first active pattern AP(1) adjacent thereto may constitute one cell transistor CTR. A portion of the second word line WL(2) and the second active pattern AP(2) adjacent thereto may constitute another cell transistor CTR.

The bit lines BL may each include a polysilicon pattern 161 and a metal pattern 163 that are sequentially stacked. Although not illustrated in FIG. 4, the shield lines SHL may each have at least one of the polysilicon pattern 161 or the metal pattern 163. A level of an upper surface of each of the bit lines BL may be equal to or different from a level of an upper surface of each of the shield lines SHL. A level of a lower surface of each of the bit lines BL may be equal to or different from a level of a lower surface of each of the shield lines SHL. The metal pattern 163 may include a conductive metal nitride (e.g., titanium nitride, tantalum nitride, etc.) and metal (e.g., tungsten, titanium, tantalum, etc.). The metal pattern 163 may also include a metal silicide such as titanium silicide, cobalt silicide, or nickel silicide.

The active patterns AP may be formed of a single crystalline semiconductor material, an oxide semiconductor or a two-dimensional semiconductor material. The oxide semiconductor may be an indium gallium zinc oxide. The two-dimensional semiconductor material may be MoS₂, WS2, MoSe₂ or WSe₂. For example, the active patterns AP may be formed of single crystalline silicon.

The first active pattern AP(1) and the second active pattern AP(2) may each have a first surface S1 and a second surface S2 opposite to each other in the third direction X3. In an example, the first surfaces S1 of the first active pattern AP(1) and second active pattern AP(2) may be in contact with the polysilicon pattern 161 of the bit line BL, and, when the polysilicon pattern 161 is not provided, in contact with the metal pattern 163.

The first active pattern AP(1) and the second active pattern AP(2) may each have a first side surface SS1 and a second side surface SS2 opposite to each other in the first direction X1. The first side surface SS1 of the first active pattern AP(1) may be adjacent to the first word line WL(1), and the second side surface SS2 of the second active pattern AP(2) may be adjacent to the second word line WL(2).

The first and second impurity regions IM1 and IM2 may be regions doped with N-type or P-type impurities in the first active pattern AP(1) and the second active pattern AP(2). The channel region CH may not be doped with impurities or may be doped with impurities of a conductivity type different from that of the impurities of the first and second impurity regions IM1 and IM2.

The channel regions CH of the first active pattern AP(1) and second active pattern AP(2) may be controlled by the first and second word lines WL(1) and WL(2) and the back gate lines BGL when a semiconductor element operates.

The back gate lines BGL may be arranged spaced a certain distance apart from each other in the first direction X1 on the bit lines BL. The back gate lines BGL may extend in the second direction X2 across the bit lines BL.

The back gate lines BGL may have a lower height than the first active pattern AP(1) and the second active pattern AP(2) in a vertical direction (e.g., the third direction X3). The back gate line BGL may have a first surface close to the bit line BL and a second surface close to the storage node contact BC. The first and second surfaces of the back gate line BGL may be vertically spaced apart from the first and second surfaces S1 and S2 of the first active pattern AP(1) and second active pattern AP(2).

A level of an upper surface of each of the back gate lines BGL may be equal to or different from a level of an upper surface of each of the word lines WL. A level of a lower surface of each of the back gate lines BGL may be equal to or different from a level of a lower surface of each of the word lines WL.

The first word line WL(1), the second word line WL(2), and the back gate lines BGL may include, for example, doped polysilicon, conductive metal nitride (e.g., titanium nitride, tantalum nitride, etc.) and metal (e.g., tungsten, titanium, tantalum, etc.), conductive metal silicide, conductive metal oxide, or a combination thereof.

When a semiconductor memory device operates, a negative voltage may be applied to the back gate lines BGL, and the back gate lines BGL may increase a threshold voltage of a vertical channel transistor. That is, deterioration of leakage current characteristics, due to a reduction in the threshold voltage caused by scaling down the vertical channel transistor, may be prevented.

A portion of each of the first lower cell interlayer insulating layer ILb and the first upper cell interlayer insulating layer ILa may include layers 111, 115, Gox1, Gox2, 131, 141, 143, 153, 155, 210, 231, and 245 formed of an insulating material. A first insulating pattern 111 may be disposed between the first active pattern AP(1) and second active pattern AP(2) adjacent to each other in the first direction X1. The first insulating pattern 111 may be disposed between the second impurity regions IM2 of the first active pattern AP(1) and second active pattern AP(2). The first insulating pattern 111 may include, for example, a silicon oxide layer, a silicon oxynitride layer, or a silicon nitride layer.

The second gate insulating layer Gox2 may be disposed between each back gate line BGL and the first and second active patterns AP(1) and AP(2) and between the back gate line BGL and the first insulating pattern 111. The second gate insulating layer Gox2 may include vertical portions on (e.g., covering) two side surfaces of the back gate line BGL and a horizontal portion connecting the vertical portions. The horizontal portion of the second gate insulating layer Gox2 may be closer to the storage node contact BC than the bit line BL, and may be on (e.g., may cover) the second surface of the back gate line BGL.

A back gate capping pattern 115 may be disposed between the bit lines BL and the back gate line BGL. The back gate capping pattern 115 may be formed of an insulating material, and a lower surface of the back gate capping pattern 115 may be in contact with the polysilicon pattern 161 of the bit lines BL. The back gate capping pattern 115 may be disposed between the vertical portions of the second gate insulating layer Gox2. A thickness of the back gate capping pattern 115 between the bit lines BL may be different from a thickness of the back gate capping pattern 115 on the bit lines BL.

The first gate insulating layer Gox1 may be on (e.g., may cover) the first side surface SS1 of the first active pattern AP(1) and the second side surface SS2 of the second active pattern AP(2). The first gate insulating layer Gox1 may have a substantially uniform thickness. The first gate insulating layers Gox1 may each include a vertical portion VP adjacent to the first and second active patterns AP(1) and AP(2) and a horizontal portion HP protruding from the vertical portion VP in the first direction X1.

For example, a pair of the first and second word lines WL(1) and WL(2) may be disposed on the horizontal portion HP of each of the first gate insulating layers Gox1. The first gate insulating layers Gox1 may be arranged spaced apart from each other and may be mirror symmetrical to each other.

A second insulating pattern 143 may be disposed between the horizontal portion HP of the first gate insulating layer Gox1 and the storage node contacts BC. For example, the second insulating pattern 143 may include silicon oxide. First and second etch stop layers 131 and 141 may be arranged between the second insulating pattern 143 and the second impurity regions IM2 of the first and second active patterns AP(1) and AP(2).

On the first gate insulating layer Gox1, the first and second word lines WL(1) and WL(2) may be separated from each other by a third insulating pattern 155. The third insulating pattern 155 may extend in the second direction X2 between the first and second word lines WL(1) and WL(2). A first capping layer 153 may be disposed between the third insulating pattern 155 and the first and second word lines WL(1) and WL(2). The first capping layer 153 may have a substantially uniform thickness.

The storage node contacts BC may penetrate an interlayer insulating layer 231, an upper insulating layer 245, and an etch stop layer 210 and may be connected to the first and second active patterns AP(1) and AP(2) respectively. The storage node contacts BC may have a lower width that is larger than an upper width thereof (e.g., in the first direction X1). The storage node contacts BC adjacent to each other may be separated from each other by the upper insulating layer 245. The storage node contacts BC may each have various shapes such as a circular shape, elliptical shape, rectangular shape, square shape, rhombic shape, and hexagonal shape in a plan view. The storage node contacts BC may be arranged in a matrix form along the second direction X2 and the first direction X1. The storage node contacts BC may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but are not limited thereto.

The storage node contacts BC may be in contact with the landing pads LP. The landing pads LP may each have various shapes such as a circular shape, elliptical shape, rectangular shape, square shape, rhombic shape, and hexagonal shape in a plan view. The landing pads LP may completely vertically overlap or partially vertically overlap the storage node contacts BC. As used herein, “an element A overlaps an element B in a first direction” (or similar language) means that there is at least one straight line that extends in the first direction and intersects both the elements A and B. The landing pads LP may be arranged in a matrix form along the second direction X2 and the first direction X1 in a plan view. In other embodiments, the landing pads LP may be arranged in a form of a honeycomb in a plan view. The landing pads LP may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but are not limited thereto.

The landing pads LP are in contact with the first electrodes BE. The first electrodes BE may be electrically connected to the first and second active patterns AP(1) and AP(2), respectively. The first electrodes BE may each have a pillar shape or a hollow cup shape.

The first electrodes BE may be arranged in a matrix form or a form of a honeycomb along the second direction X2 and the first direction X1. The first electrodes BE may completely or partially overlap the landing pads LP. The first electrodes BE may be in contact with a portion or entirety of a lower surface/upper surface of the landing pads LP. The first electrodes BE may be arranged at regular intervals. The first electrodes BE may include at least one of impurity-doped polysilicon, metal, a metal oxide layer, or a metal nitride layer. The first electrodes BE may include a titanium nitride layer.

A portion of sidewalls of the first electrodes BE may be in contact with support patterns SSP. The support patterns SSP may prevent the first electrodes BE from falling. The support patterns SSP may have a shape of a plate or mesh in which a plurality of holes are formed in a plan view. The support patterns SSP may be formed as a single layer or two or more layers. The support patterns SSP may be formed as, for example, a single layer or multi-layer of at least one of a silicon nitride (SiN) layer, a silicon boron nitride (SiBN) layer, or a silicon carbon nitride (SiCN) layer.

The dielectric layer DL is conformally on (e.g., conformally covers) the first electrodes BE and the support patterns SSP. The dielectric layer DL may be formed as, for example, a single layer or multi-layer of a silicon oxide layer or metal oxide layer such as an aluminum oxide layer formed of a material having a higher dielectric constant than a silicon oxide layer. The dielectric layer DL is covered with the second electrode UE. That is, the second electrode UE is on the dielectric layer DL. The second electrode UE may be formed as a single layer or multi-layer of at least one of a titanium nitride layer, tungsten layer, impurity-doped polysilicon layer, or impurity-doped silicon germanium layer. A sidewall of the second electrode UE may be aligned with a sidewall of the dielectric layer DL. The first electrodes BE, the dielectric layer DL, and the second electrode UE may constitute the capacitors CAP.

A connection relationship between the first lower cell structure CS1b, the peripheral structure PS, and the first upper cell structure CS1a in the semiconductor memory device 1000a of FIGS. 2 and 3 may be the same as or similar to that described with reference to FIG. 1B.

At least one of the first lower cell structure CS1b or the first upper cell structure CS1a may further include a portion of the core circuit unit and/or a portion of the peripheral circuit unit. To this end, the at least one of the first lower cell structure CS1b or the first upper cell structure CS1a may further include peripheral transistors, a power capacitor, and the like.

In a semiconductor memory device according to the inventive concepts, the first upper and lower cell structures CS1a and CS1b are arranged on and under the peripheral structure PS, and thus a connection distance between the peripheral structure PS and the first upper cell structure CS1a may be similar to a connection distance between the peripheral structure PS and the first lower cell structure CS1b. Therefore, signal transfer speeds between the peripheral structure PS and the first upper and lower cell structures CS1a and CS1b may be similar, and thus a defect caused by signal delay may be prevented and a semiconductor memory device with improved reliability may be achieved. Furthermore, since the first upper and lower cell structures CS1a and CS1b are arranged on and under the peripheral structure PS, line routing may be performed more easily. Furthermore, since a peripheral structure and cell structures have a stacked structure, and the cell transistors CTR have a VCT structure in each of the cell structures CS1a and CS1b, a memory capacity of a semiconductor memory device may be increased and a horizontal size of the semiconductor memory device may be reduced. Accordingly, a highly integrated semiconductor element may be provided.

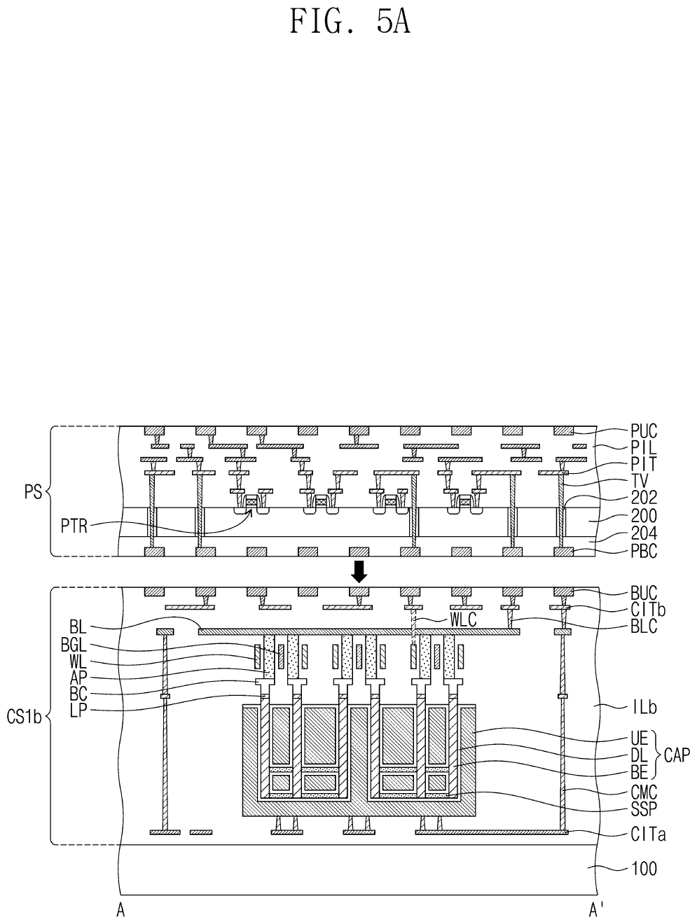

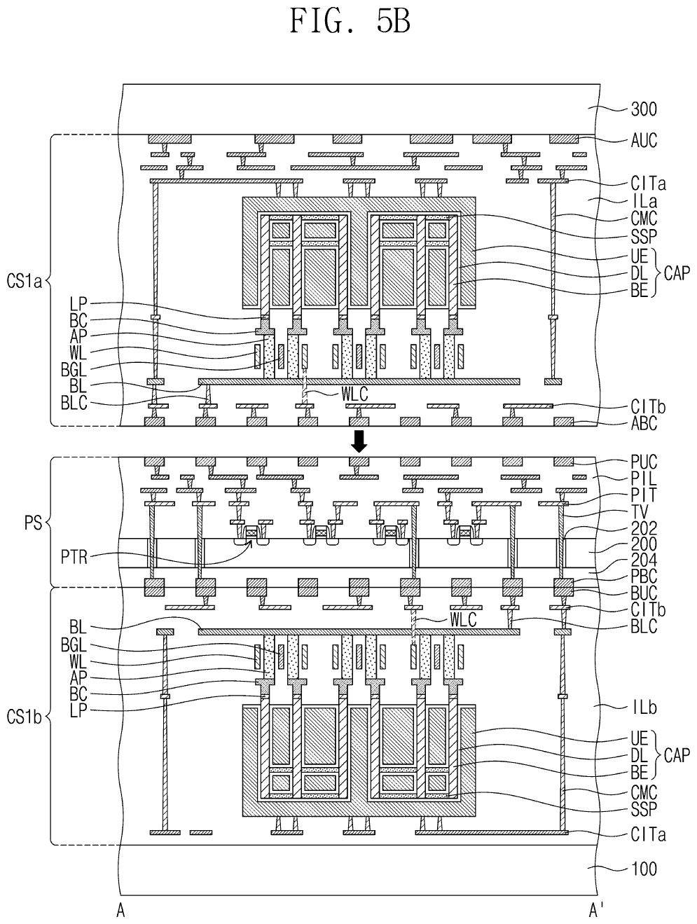

FIGS. 5A and 5B are diagrams sequentially illustrating a process of manufacturing the semiconductor memory device of FIG. 2.

Referring to FIG. 5A, the first lower cell structure CS1b is formed on the first support substrate 100. The peripheral structure PS is placed on the first lower cell structure CS1b so that a lower surface of the peripheral lower insulating layer 204 is in contact with an upper surface of the first lower cell interlayer insulating layer ILb and lower surfaces of the peripheral lower pads PBC are in contact with upper surfaces of the first lower cell pads BUC. Furthermore, a thermal compression process is performed to bond the peripheral structure PS onto the first lower cell structure CS1b.

Referring to FIG. 5B, the first upper cell structure CS1a is formed on a second support substrate 300. The second support substrate 300 is turned over, and the first upper cell structure CS1a is placed on the peripheral structure PS. The first upper cell structure CS1a is bonded onto the peripheral structure PS by performing a thermal compression process after bringing an upper surface of the peripheral interlayer insulating layer PIL into contact with a lower surface of the first upper cell interlayer insulating layer ILa and bringing the peripheral upper pads PUC into contact with the first upper cell pads ABC.

Subsequently, the second support substrate 300 may be removed so as to expose an upper surface of the first upper cell interlayer insulating layer ILa and upper surfaces of the second upper cell pads AUC. Although FIGS. 5A and 5B illustrate that the first upper cell structure CS1a is bonded onto the peripheral structure PS after bonding the peripheral structure PS onto the first lower cell structure CS1b, the bonding processes may be performed simultaneously. That is, the first lower cell structure CS1b, the peripheral structure PS, and the first upper cell structure CS1a may be simultaneously bonded by performing a single thermal compression process after sequentially stacking the peripheral structure PS and the first upper cell structure CS1a on the first lower cell structure CS1b.

The first lower cell structure CS1b, the peripheral structure PS, and the first upper cell structure CS1a may be bonded in a wafer-to-wafer manner.

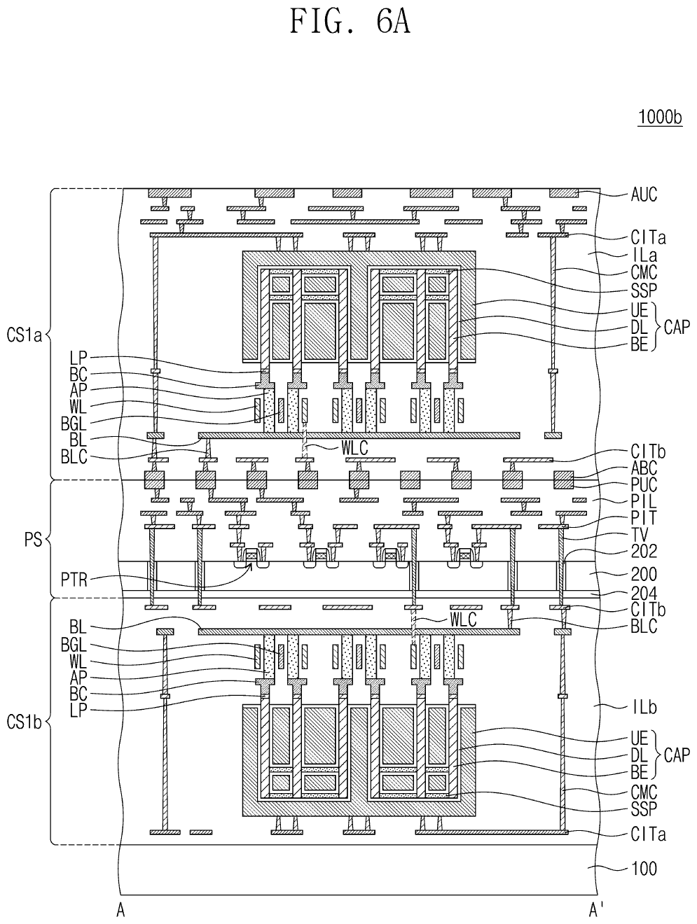

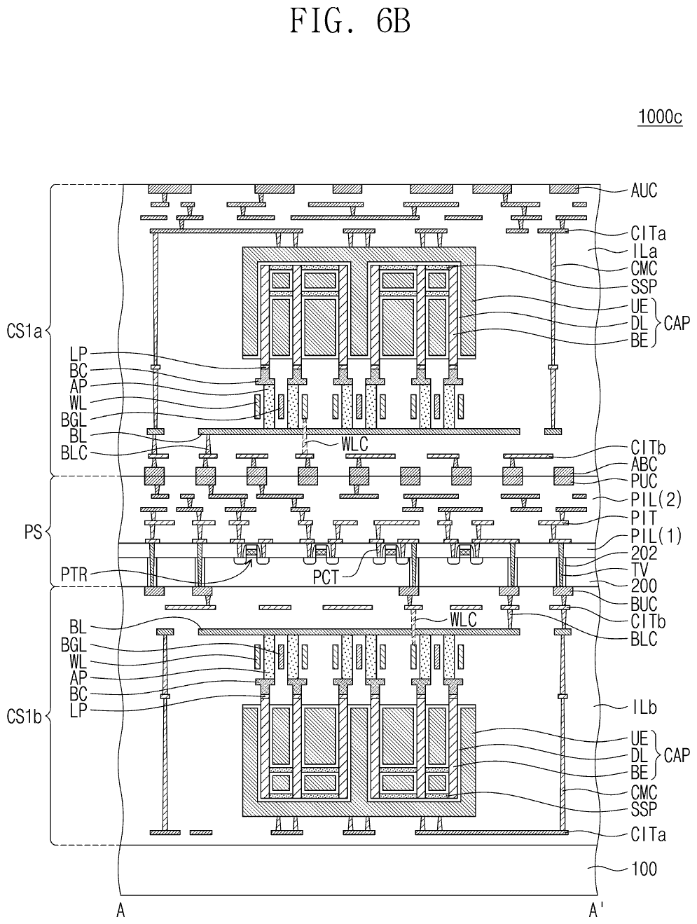

FIG. 6A is a cross-sectional view of the semiconductor memory device of FIG. 2 taken along line A-A′ according to embodiments of the inventive concepts.

Referring to FIG. 6A, in a semiconductor memory device 1000b according to the present example, the peripheral structure PS may not include the peripheral lower pads PBC of FIG. 3. The first lower cell structure CS1b may not include the first lower cell pads BUC of FIG. 3. An upper surface of the first lower cell interlayer insulating layer ILb may be in direct contact with a lower surface of the peripheral lower insulating layer 204. The through via TV may penetrate the peripheral substrate 200, the peripheral lower insulating layer 204, and a portion of the first lower cell interlayer insulating layer ILb and connect one of the peripheral lines PIT to one of the second cell lines CITb of the first lower cell structure CS1b. Other structures may be the same as or similar to those described with reference to FIGS. 1B to 4.

FIG. 6B is a cross-sectional view of the semiconductor memory device of FIG. 2 taken along line A-A′ according to embodiments of the inventive concepts.

Referring to FIG. 6B, in a semiconductor memory device 1000c according to the present example, the peripheral structure PS may not include the peripheral lower insulating layer 204. A lower surface of the peripheral substrate 200 may be in direct contact with an upper surface of the first lower cell interlayer insulating layer ILb of the first lower cell structure CS1b. The peripheral interlayer insulating layer PIL may include a first peripheral interlayer insulating layer PIL(1) and a second peripheral interlayer insulating layer PIL(2) that are sequentially stacked. The first peripheral interlayer insulating layer PIL(1) may be on (e.g., may cover) the peripheral transistors PTR and an upper surface of the peripheral substrate 200. The first peripheral interlayer insulating layer PIL(1) and the second peripheral interlayer insulating layer PIL(2) may each have a single-layer or multi-layer structure of at least one of silicon oxide, silicon nitride, silicon oxynitride, SiCN, SiOCH, or porous insulator. Peripheral contact plugs PCT may penetrate the first peripheral interlayer insulating layer PIL(1) and may be connected to source/drain regions of the peripheral transistors PTR. The peripheral lines PIT may be arranged in the second peripheral interlayer insulating layer PIL(2).

The peripheral substrate insulating pattern 202 may be disposed in the peripheral substrate 200. The peripheral substrate insulating pattern 202 may penetrate the peripheral substrate 200. The through via TV may penetrate the first peripheral interlayer insulating layer PIL(1) and the peripheral substrate insulating pattern 202 and connect one of the peripheral lines PIT to the first lower cell pad BUC at an upper end of the first lower cell structure CS1b. The first lower cell pad BUC may be in direct contact with the through via TV. The first lower cell pad BUC may be in direct contact with the peripheral substrate insulating pattern 202. The through via TV may be also referred to as a through silicon dielectric via (TSDV). Other structures may be the same as or similar to those described above.

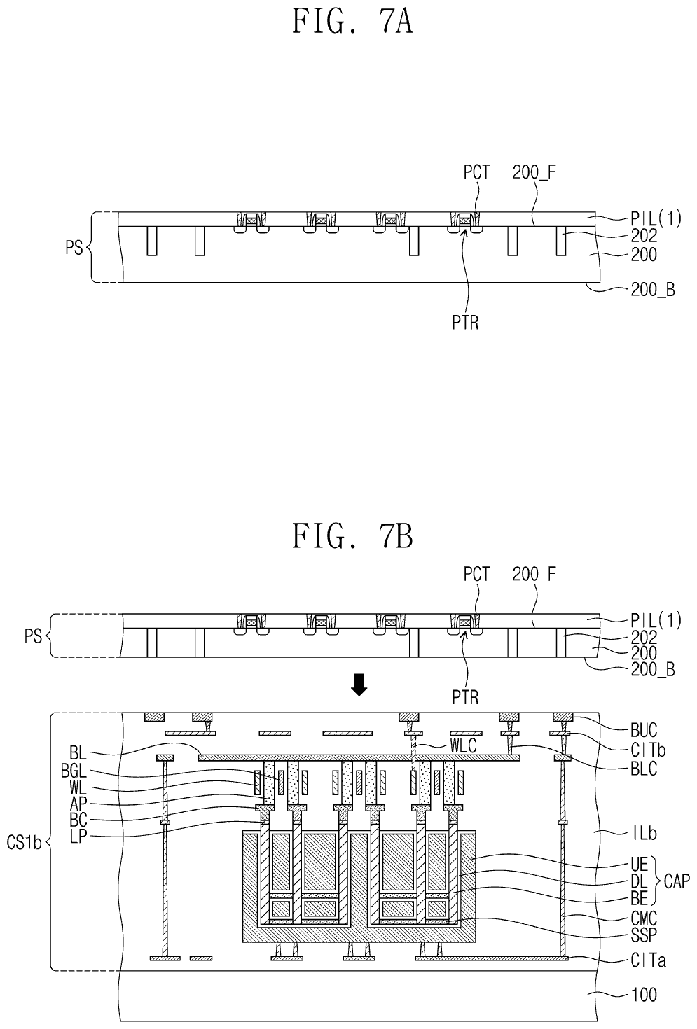

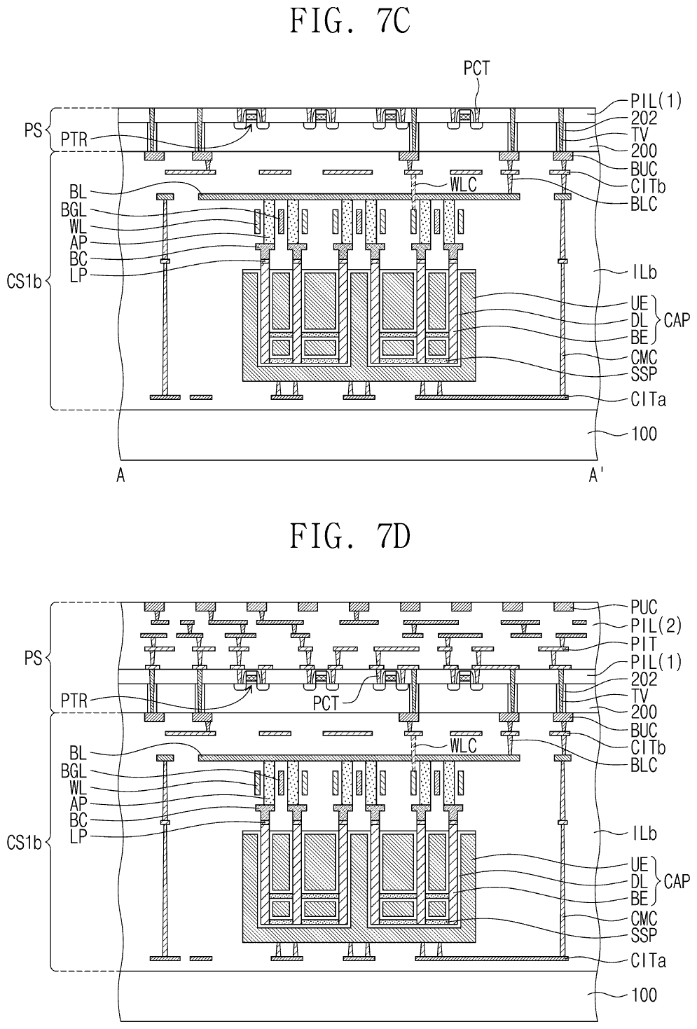

FIGS. 7A to 7D sequentially illustrate a process of manufacturing the semiconductor memory device of FIG. 6B according to embodiments of the inventive concepts.

Referring to FIG. 7A, the peripheral structure PS is manufactured. The peripheral structure PS may include the peripheral substrate 200. The peripheral substrate insulating pattern 202 may be formed in the peripheral substrate 200. A lower surface of the peripheral substrate insulating pattern 202 may be spaced apart from a lower surface 200_B of the peripheral substrate 200. The peripheral transistors PTR, the peripheral contact plugs PCT, and the first peripheral interlayer insulating layer PIL(1) are formed on a front side 200_F of the peripheral substrate 200.

Referring to FIGS. 7A and 7B, a portion of the peripheral substrate 200 may be removed by performing a back grinding process on the lower surface 200_B of the peripheral substrate 200, and the peripheral substrate insulating pattern 202 may be exposed. The peripheral structure PS is placed on an upper surface of the first lower cell structure CS1b.

Referring to FIGS. 7B and 7C, a thermal compression process is performed to bond the peripheral structure PS to the first lower cell structure CS1b. Furthermore, the through via TV penetrating the first peripheral interlayer insulating layer PIL(1) and the peripheral substrate insulating pattern 202 is formed. The through via TV may be in contact with the first lower cell pad BUC.

Referring to FIG. 7D, the second peripheral interlayer insulating layer PIL(2), the peripheral lines PIT, the peripheral upper pads PUC, and the like may be formed on the first peripheral interlayer insulating layer PIL(1) by performing a back end of line (BEOL) process. Accordingly, the peripheral structure PS of FIG. 6B may be completed. Subsequently, referring to FIG. 6B, the first upper cell structure CS1a is bonded onto the peripheral structure PS. Accordingly, the semiconductor memory device 1000c of FIG. 6B may be completed.

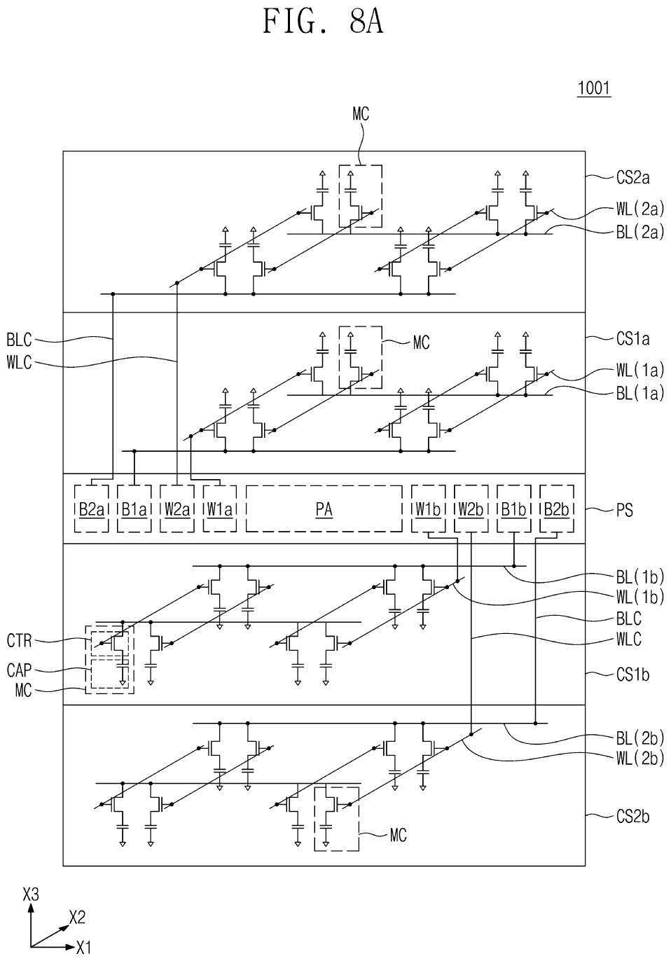

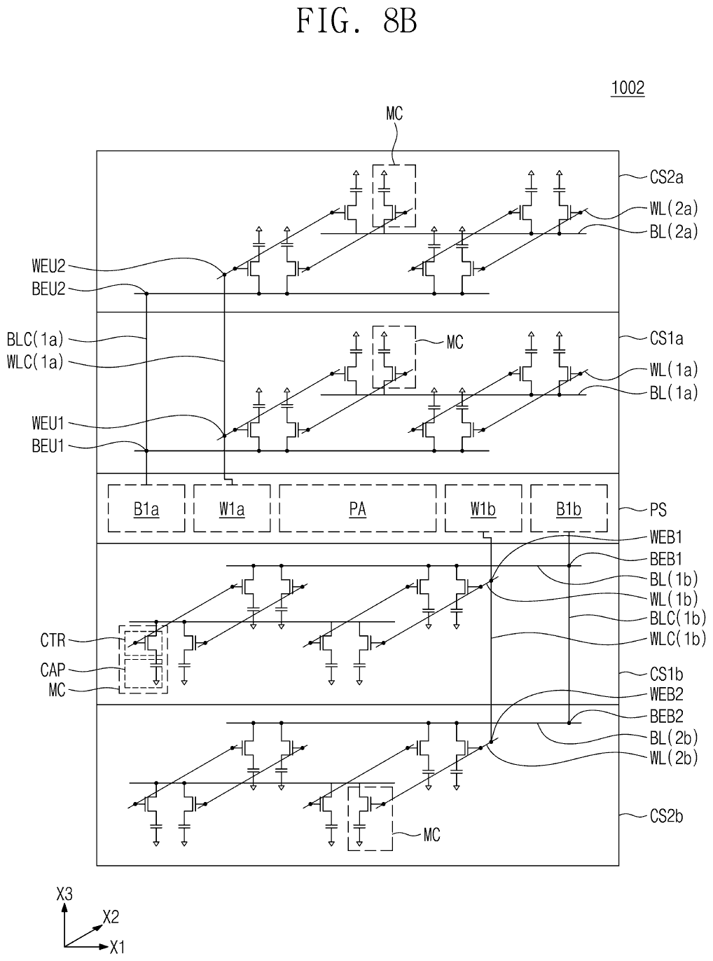

FIG. 8A is a block diagram schematically illustrating a semiconductor memory device according to embodiments of the inventive concepts.

Referring to FIG. 8A, a semiconductor memory device 1001 may further include, in addition to the structure of FIG. 1B, a second lower cell structure CS2b bonded under the first lower cell structure CS1b and a second upper cell structure CS2a bonded on the first upper cell structure CS1a. The second lower cell structure CS2b and the second upper cell structure CS2a may be respectively the same as or similar to the first lower cell structure CS1b and the first upper cell structure CS1a described with reference to FIGS. 1B to 4. The second lower cell structure CS2b and the second upper cell structure CS2a may each include the memory cells MC, the bit lines BL, and the word lines WL that are two-dimensionally arranged on a plane extending in the first direction X1 and the second direction X2.

The bit lines BL may include second upper bit lines BL(2a) belonging to the second upper cell structure CS2a and second lower bit lines BL(2b) belonging to the second lower cell structure CS2b. The word lines WL may include second upper word lines WL(2a) belonging to the second upper cell structure CS2a and second lower word lines WL(2b) belonging to the second lower cell structure CS2b.

The peripheral structure PS may further include a second upper sense amplifier B2a, a second lower sense amplifier B2b, a second upper word line driver W2a, and a second lower word line driver W2b.

One end of each of the second upper bit lines BL(2a) of the second upper cell structure CS2a may be connected to the second upper sense amplifier B2a of the peripheral structure PS through the bit line contact plugs BLC. One end of each of the second lower bit lines BL(2b) of the second lower cell structure CS2b may be connected to the second lower sense amplifier B2b of the peripheral structure PS through the bit line contact plugs BLC.

One end of each of the second upper word lines WL(2a) of the second upper cell structure CS2a may be connected to the second upper word line driver W2a of the peripheral structure PS through the word line contact plugs WLC. One end of each of the second lower word lines WL(2b) of the second lower cell structure CS2b may be connected to the second lower word line driver W2b of the peripheral structure PS through the word line contact plugs WLC. Other structures may be the same as or similar to those described with reference to FIGS. 1B to 4.

In the present example, the number of the sense amplifiers B1a, B2a, B1b, and B2b and the number of the word line drivers W1a, W2a, W1b, and W2b in the peripheral structure PS are not limited to the above numbers, and may be proportional to the number of cell structures arranged on and under the peripheral structure PS.

FIG. 8B is a block diagram schematically illustrating a semiconductor memory device according to embodiments of the inventive concepts.

Referring to FIG. 8B, a semiconductor memory device 1002 may further include, in addition to the structure of FIG. 1B, a second lower cell structure CS2b bonded under the first lower cell structure CS1b and a second upper cell structure CS2a bonded on the first upper cell structure CS1a. A memory cell array of the first lower cell structure CS1b may be connected in parallel with a memory cell array of the second lower cell structure CS2b. A memory cell array of the first upper cell structure CS1a may be connected in parallel with a memory cell array of the second upper cell structure CS2a.

One of the first upper bit line contact plugs BLC(1a) may connect a first end BEU1 of one of the first upper bit lines BL(1a) of the first upper cell structure CS1a and a second end BEU2 of one of the second upper bit lines BL(2a) of the second upper cell structure CS2a to the first upper sense amplifier B1a. The first end BEU1 and the second end BEU2 may vertically overlap each other.

One of the first upper word line contact plugs WLC(1a) may connect a first end WEU1 of one of the first upper word lines WL(1a) of the first upper cell structure CS1a and a second end WEU2 of one of the second upper word lines WL(2a) of the second upper cell structure CS2a to the first upper word line driver W1a. The first end WEU1 and the second end WEU2 may vertically overlap each other.

One of the first lower bit line contact plugs BLC(1b) may connect a first end BEB1 of one of the first lower bit lines BL(1b) of the first lower cell structure CS1b and a second end BEB2 of one of the second lower bit lines BL(2b) of the second lower cell structure CS2b to the first lower sense amplifier B1b. The first end BEB1 and the second end BEB2 may vertically overlap each other.

One of the first lower word line contact plugs WLC(1b) may connect a first end WEB1 of one of the first lower word lines WL(1b) of the first lower cell structure CS1b and a second end WEB2 of one of the second lower word lines WL(2b) of the second lower cell structure CS2b to the first lower word line driver W1b. The first end WEB1 and the second end WEB2 may vertically overlap each other.

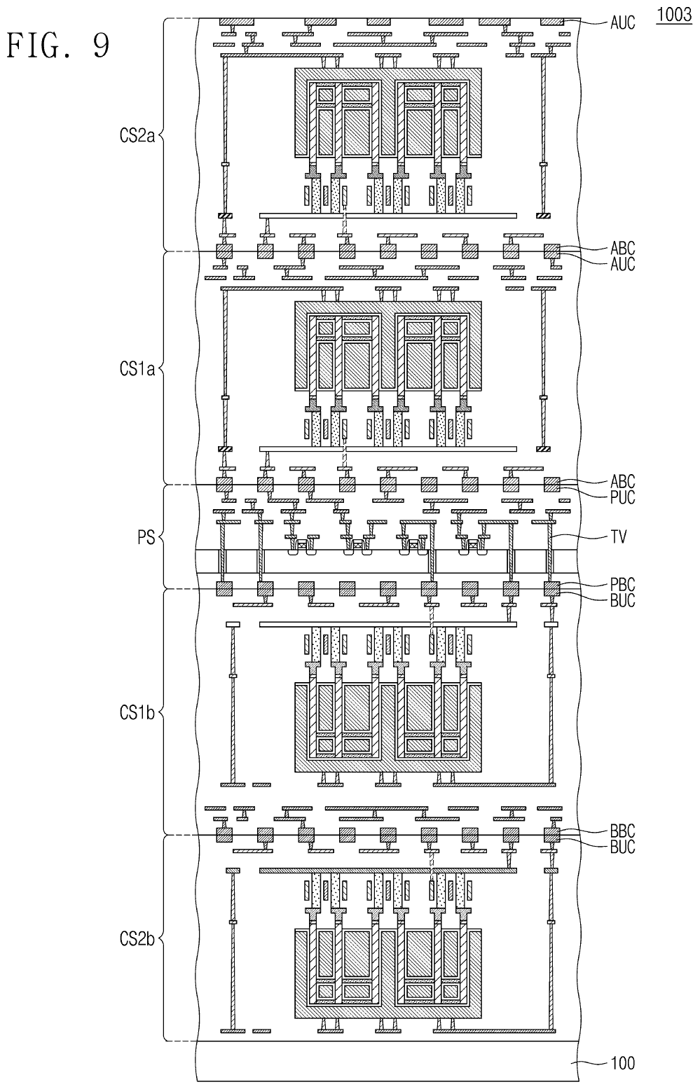

FIG. 9 is a cross-sectional view of a semiconductor memory device according to embodiments of the inventive concepts.

Referring to FIG. 9, a semiconductor memory device 1003 according to the present example may further include, in addition to the semiconductor memory device 1000a of FIG. 3, a second lower cell structure CS2b bonded under the first lower cell structure CS1b and a second upper cell structure CS2a bonded on the first upper cell structure CS1a. The second lower cell structure CS2b and the second upper cell structure CS2a may be respectively the same as or similar to the first lower cell structure CS1b and the first upper cell structure CS1a described with reference to FIGS. 8B and 2 to 4.

The first lower cell pads BUC at an upper end of the second lower cell structure CS2b may be respectively bonded to second lower cell pads BBC at a lower end of the first lower cell structure CS1b so as to electrically connect the second lower cell structure CS2b to the first lower cell structure CS1b.

The first upper cell pads ABC at a lower end of the second upper cell structure CS2a may be respectively bonded to the second upper cell pads AUC at an upper end of the first upper cell structure CS1a so as to electrically connect the second upper cell structure CS2a to the first upper cell structure CS1a.

In another example, a connection structure between the peripheral structure PS, the first and second upper cell structures CS1a and CS2a, and the first and second lower cell structures CS1b and CS2b may be the same as or similar to that illustrated in FIGS. 6A and 6B. Other structures may be the same as or similar to those described above.

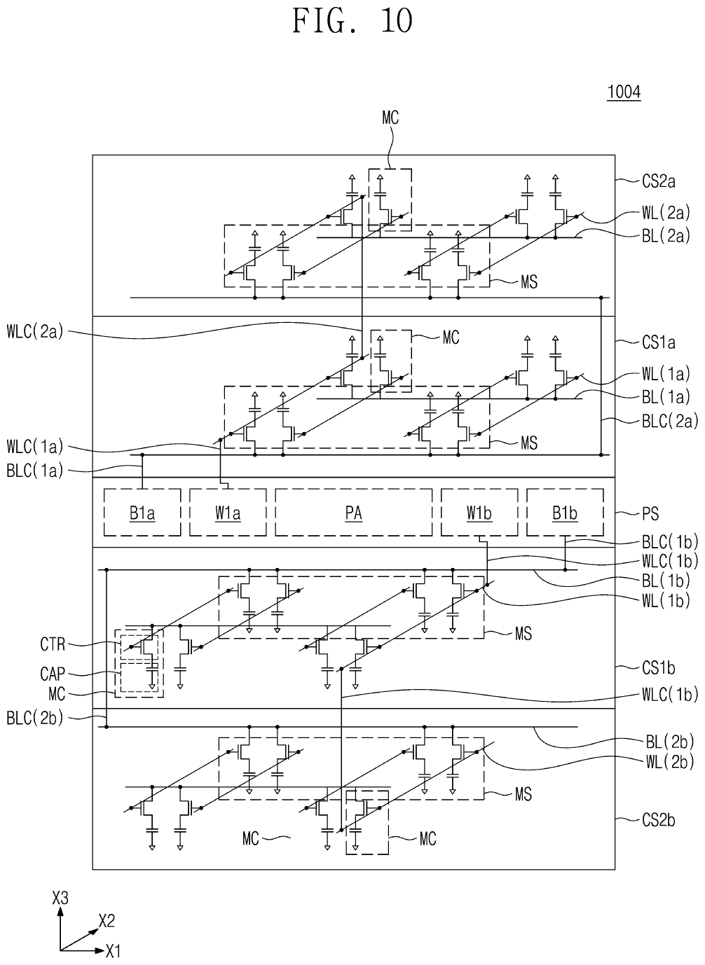

FIG. 10 is a block diagram schematically illustrating a semiconductor memory device according to embodiments of the inventive concepts.

Referring to FIG. 10, in a semiconductor memory device 1004, a memory cell array of the first lower cell structure CS1b may be connected in series with a memory cell array of the second lower cell structure CS2b. A memory cell array of the first upper cell structure CS1a may be connected in series with a memory cell array of the second upper cell structure CS2a. The first lower cell structure CS1b, the second lower cell structure CS2b, the first upper cell structure CS1a, and the second upper cell structure CS2a may each include a memory cell set (or memory cell string) MS connected to the same bit line BL. In each of the first lower cell structure CS1b, the second lower cell structure CS2b, the first upper cell structure CS1a, and the second upper cell structure CS2a, the memory cell set MS may be provided in plurality and arranged in the second direction X2.

One memory cell set MS of the first upper cell structure CS1a may be connected in series with one memory cell set MS of the second upper cell structure CS2a by one first upper bit line contact plug BLC(1a) and one second upper bit line contact plug BLC(2a). The first upper bit line contact plug BLC(1a) and the second upper bit line contact plug BLC(2a) may not overlap each other and may be arranged at opposite positions.

One memory cell set MS of the first lower cell structure CS1b may be connected in series with one memory cell set MS of the second lower cell structure CS2b by one first lower bit line contact plug BLC(1b) and one second lower bit line contact plug BLC(2b). The first lower bit line contact plug BLC(1b) and the second lower bit line contact plug BLC(2b) may not overlap each other and may be arranged at opposite positions. Other structures may be the same as or similar to those illustrated in FIG. 8B.

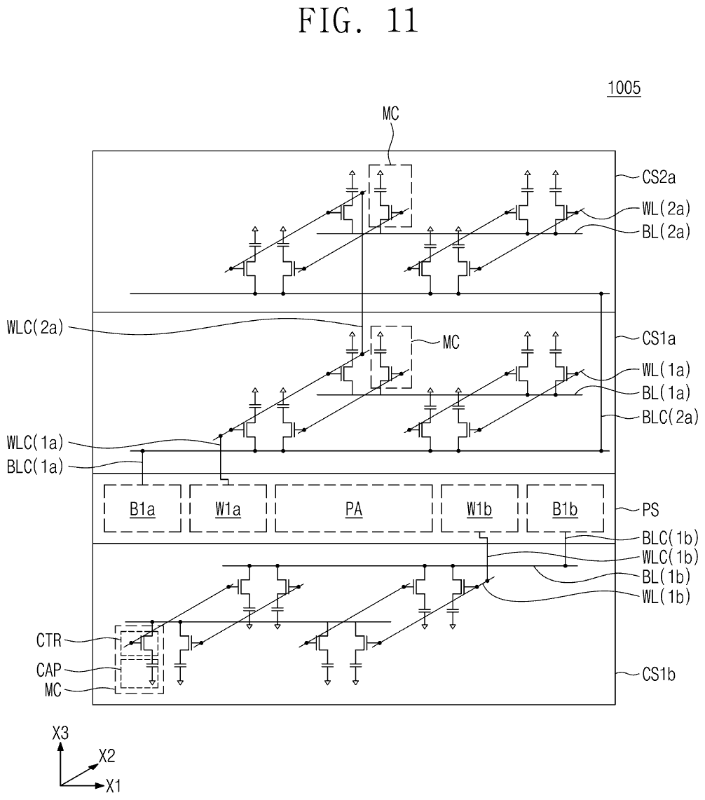

FIG. 11 is a block diagram schematically illustrating a semiconductor memory device according to embodiments of the inventive concepts.

Referring to FIG. 11, in a semiconductor memory device 1005, the number of upper cell structures arranged on the peripheral structure PS may be different from the number of lower cell structures arranged under the peripheral structure PS. In detail, the semiconductor memory device 1005 may not include the second lower cell structure CS2b in the structure illustrated in FIG. 8B or FIG. 10.

Other structures may be the same as or similar to those illustrated in FIG. 8B or FIG. 10. In the present example, the second lower cell structure CS2b is excluded, two upper cell structures CS1a and CS2a are arranged on the peripheral structure PS, and one lower cell structure CS1b is disposed under the peripheral structure PS in the structure illustrated in FIG. 8B or FIG. 10. However, embodiments of the inventive concepts are not limited thereto, and one upper cell structure CS1a may be disposed on the peripheral structure PS, and two lower cell structures CS1b and CS2b may be arranged under the peripheral structure PS in other embodiments. The number of the upper cell structures and the number of the lower cell structures are not limited thereto, and may be any natural number equal to or greater than 3 in some embodiments.

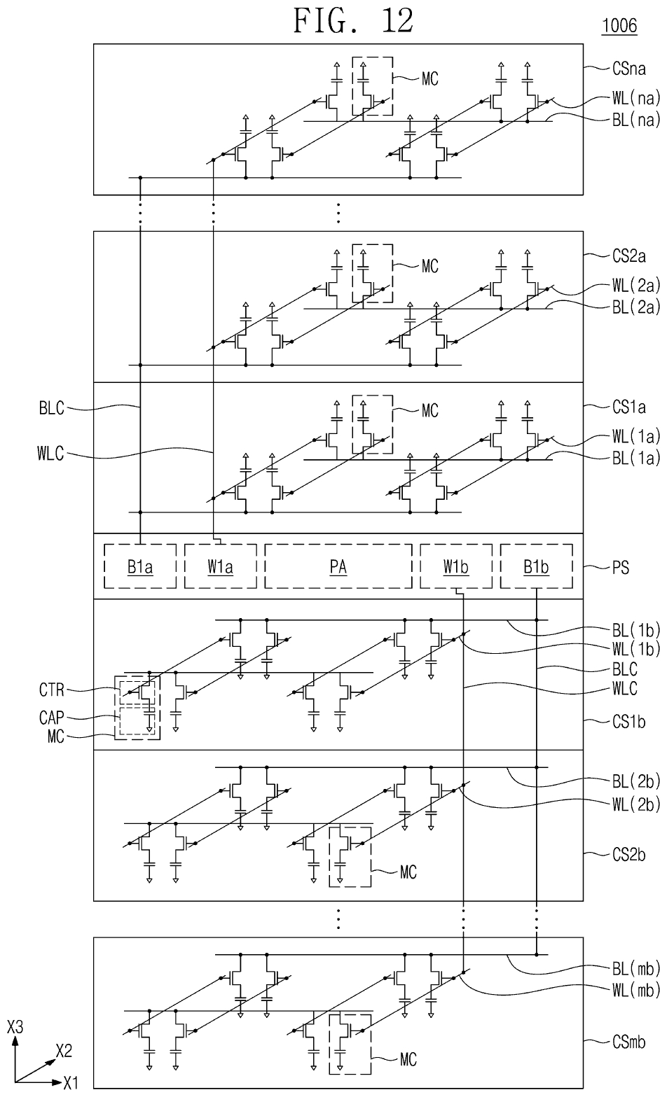

FIG. 12 is a block diagram schematically illustrating a semiconductor memory device according to embodiments of the inventive concepts.

Referring to FIG. 12, in a semiconductor memory device 1006 according to the present example, n upper cell structures CS1a to CSna may be stacked on the peripheral structure PS, and m lower cell structures CS1b to CSmb may be stacked under the peripheral structure PS. Here, n may be equal to or different from m. In the present example, n and m may be each independently a natural number equal to or greater than 3. Memory cell arrays of the upper cell structures CS1a to CSna may be connected in parallel or in series with each other. Memory cell arrays of the lower cell structures CS1b to CSmb may be connected in parallel or in series with each other. Other structures may be the same as or similar to those described with reference to FIGS. 8A to 11.

In a semiconductor memory device according to embodiments of the inventive concepts, connection distances between a peripheral structure and cell structures approximate each other since the cell structures are arranged on and under the peripheral structure, and thus the reliability of the semiconductor memory device may be improved. Furthermore, since the cell structures have a VCT structure, the horizontal size of the semiconductor memory device may be reduced. Accordingly, a highly integrated semiconductor element may be provided.

Although example embodiments of the present disclosure have been described with reference to the accompanying drawings, those of ordinary skill in the art will understand that the present disclosure can be carried out in other specific forms without changing the technical concepts or essential features. Therefore, the above embodiments should be considered illustrative and should not be construed as limiting. The embodiments of FIGS. 1A to 12 may be combined with each other.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor memory device comprising:
a peripheral structure;
a first upper cell structure on the peripheral structure; and
a first lower cell structure on an opposite side of the peripheral structure from the first upper cell structure,
wherein each of the first upper cell structure and the first lower cell structure comprises:
a first active pattern perpendicular to an upper surface of the peripheral structure;
a first word line adjacent to a side surface of the first active pattern and extending in a first direction parallel to the upper surface of the peripheral structure; and
a first bit line electrically connected to a first end of the first active pattern and extending in a second direction intersecting the first direction.

2. The semiconductor memory device of claim 1, wherein the peripheral structure comprises:
a peripheral substrate;
peripheral transistors and peripheral lines on an upper surface of the peripheral substrate;
a peripheral interlayer insulating layer on the peripheral transistors and the peripheral lines;
a peripheral lower insulating layer on a lower surface of the peripheral substrate;
a peripheral upper pad at an upper end of the peripheral interlayer insulating layer; and
a through via extending into the peripheral substrate and electrically connected to one of the peripheral lines.

3. The semiconductor memory device of claim 2, wherein the first upper cell structure further comprises a first upper cell interlayer insulating layer and a first upper cell pad at a lower end of the first upper cell interlayer insulating layer and in contact with the peripheral upper pad, and
wherein the first lower cell structure further comprises a first lower cell interlayer insulating layer and a first lower cell line in the first lower cell interlayer insulating layer and electrically connected to the through via.

4. The semiconductor memory device of claim 3, wherein the first lower cell structure further comprises a first lower cell pad at an upper end of the first lower cell interlayer insulating layer,
wherein the peripheral structure further comprises a peripheral lower pad at a lower end of the peripheral lower insulating layer and in contact with the first lower cell pad, and
wherein the through via extends into the peripheral lower insulating layer and is in contact with the peripheral lower pad.

5. The semiconductor memory device of claim 1, wherein each of the first upper cell structure and the first lower cell structure further comprises:
a first electrode electrically connected to a second end of the first active pattern;
a dielectric layer on the first electrode; and
a second electrode on the dielectric layer,
wherein the second end is opposite to the first end of the first active pattern, and
wherein the first bit line is closer to the peripheral structure than the first electrode in each of the first upper cell structure and the first lower cell structure.

6. The semiconductor memory device of claim 1, wherein the peripheral structure comprises a first upper sense amplifier, a first lower sense amplifier, a first upper word line driver, and a first lower word line driver,
wherein an end of the first bit line of the first upper cell structure is electrically connected to the first upper sense amplifier,
wherein an end of the first word line of the first upper cell structure is electrically connected to the first upper word line driver,
wherein an end of the first bit line of the first lower cell structure is electrically connected to the first lower sense amplifier, and
wherein an end of the first word line of the first lower cell structure is electrically connected to the first lower word line driver.

7. The semiconductor memory device of claim 1, further comprising:
a second upper cell structure on the first upper cell structure; and
a second lower cell structure on an opposite side of the first lower cell structure from the peripheral structure,
wherein each of the second upper cell structure and the second lower cell structure comprises:
a second active pattern perpendicular to the upper surface of the peripheral structure;
a second word line adjacent to a side surface of the second active pattern and extending in the first direction; and
a second bit line electrically connected to a first end of the second active pattern and extending in the second direction.

8. The semiconductor memory device of claim 1, further comprising a support substrate on an opposite side of the first lower cell structure from the peripheral structure.

9. The semiconductor memory device of claim 1, wherein the first upper cell structure further comprises an external connection pad at an upper end of the first upper cell structure.

10. A semiconductor memory device comprising:
a peripheral structure;
at least one upper cell structure on the peripheral structure; and
at least one lower cell structure on an opposite side of the peripheral structure from the upper cell structure,
wherein each of the upper cell structure and the lower cell structure comprises an array of memory cells, and
wherein the peripheral structure comprises:
a peripheral substrate;
peripheral transistors and peripheral lines on an upper surface of the peripheral substrate;
a peripheral interlayer insulating layer on the peripheral transistors and the peripheral lines;
a peripheral lower insulating layer on a lower surface of the peripheral substrate;
a peripheral upper pad at an upper end of the peripheral interlayer insulating layer; and
a through via extending into the peripheral substrate and electrically connected to at least one of the peripheral lines.

11. The semiconductor memory device of claim 10, wherein the upper cell structure further comprises an upper cell interlayer insulating layer and an upper cell pad at a lower end of the upper cell interlayer insulating layer and in contact with the peripheral upper pad, and
wherein the lower cell structure further comprises a lower cell interlayer insulating layer and a lower cell line in the lower cell interlayer insulating layer and electrically connected to the through via.

12. The semiconductor memory device of claim 11, wherein the lower cell structure further comprises a lower cell pad at an upper end of the lower cell interlayer insulating layer,
wherein the peripheral structure further comprises a peripheral lower pad at a lower end of the peripheral lower insulating layer and in contact with the lower cell pad, and
wherein the through via extends into the peripheral lower insulating layer and is in contact with the peripheral lower pad.

13. The semiconductor memory device of claim 10, wherein each of the memory cells comprises a cell transistor and a cell capacitor, and wherein the cell transistor is closer to the peripheral structure than the cell capacitor in each of the upper cell structure and the lower cell structure.

14. The semiconductor memory device of claim 10, further comprising a support substrate on an opposite side of the lower cell structure from the peripheral structure.

15. The semiconductor memory device of claim 10, wherein the upper cell structure further comprises an external connection pad at an upper end of the upper cell structure.

16. A semiconductor memory device comprising:
a peripheral structure;
a first upper cell structure on the peripheral structure; and
a first lower cell structure on an opposite side of the peripheral structure from the first upper cell structure,
wherein the peripheral structure comprises:
a peripheral substrate;
peripheral transistors and peripheral lines on an upper surface of the peripheral substrate;
a peripheral interlayer insulating layer on the peripheral transistors and the peripheral lines;
a peripheral lower insulating layer on a lower surface of the peripheral substrate;
a peripheral upper pad at an upper end of the peripheral interlayer insulating layer; and
a through via extending into the peripheral substrate and electrically connected to at least one of the peripheral lines,
wherein each of the first upper cell structure and the first lower cell structure comprises:
a first active pattern perpendicular to an upper surface of the peripheral structure;
a first word line adjacent to a side surface of the first active pattern and extending in a first direction parallel to the upper surface of the peripheral structure;
a first bit line electrically connected to a first end of the first active pattern and extending in a second direction intersecting the first direction;
a first electrode electrically connected to a second end of the first active pattern;
a dielectric layer on the first electrode; and
a second electrode on the dielectric layer,
wherein the second end is opposite to the first end of the first active pattern, and
wherein the first bit line is closer to the peripheral structure than the first electrode in each of the first upper cell structure and the first lower cell structure.

17. The semiconductor memory device of claim 16, wherein the first upper cell structure further comprises a first upper cell interlayer insulating layer and a first upper cell pad at a lower end of the first upper cell interlayer insulating layer and in contact with the peripheral upper pad, and
wherein the first lower cell structure further comprises a first lower cell interlayer insulating layer and a first lower cell line in the first lower cell interlayer insulating layer and electrically connected to the through via.

18. The semiconductor memory device of claim 17, wherein the first lower cell structure further comprises a first lower cell pad at an upper end of the first lower cell interlayer insulating layer,
wherein the peripheral structure further comprises a peripheral lower pad at a lower end of the peripheral lower insulating layer and in contact with the first lower cell pad, and
wherein the through via extends into the peripheral lower insulating layer and is in contact with the peripheral lower pad.

19. The semiconductor memory device of claim 16, wherein the peripheral structure further comprises a first upper sense amplifier, a first lower sense amplifier, a first upper word line driver, and a first lower word line driver,
wherein an end of the first bit line of the first upper cell structure is electrically connected to the first upper sense amplifier,
wherein an end of the first word line of the first upper cell structure is electrically connected to the first upper word line driver,
wherein an end of the first bit line of the first lower cell structure is electrically connected to the first lower sense amplifier, and
wherein an end of the first word line of the first lower cell structure is electrically connected to the first lower word line driver.

20. The semiconductor memory device of claim 16, further comprising:
a second upper cell structure on the first upper cell structure; and
a second lower cell structure on an opposite side of the first lower cell structure from the peripheral structure,
wherein each of the second upper cell structure and the second lower cell structure comprises:
a second active pattern perpendicular to the upper surface of the peripheral structure;
a second word line adjacent to a side surface of the second active pattern and extending in the first direction; and
a second bit line electrically connected to a first end of the second active pattern and extending in the second direction.
